(19) United States
(12) Patent Application Publication
(10) Pub. No.: US 2011/0075875 A1
(43) Pub. Date: Mar. 31, 2011

(54) MEMS MICROPHONE PACKAGE

(75) Inventors: Zhi-Jiang WU, Shenzhen (CN); Yong-Ze SU, Shenzhen (CN)

(73) Assignees: AAC ACOUSTIC TECHNOLOGIES (SHENZHEN) CO., LTD, Shenzhen (CN); AMERICAN AUDIO COMPONENTS INC., La Verne, CA (US)

(21) Appl. No.: 12/694,281

(22) Filed: Jan. 27, 2010

(30) Foreign Application Priority Data
Sep. 28, 2009 (CN) 200910190504.3

(51) Int. Cl. H04R 9/08; H01L 21/02

(52) U.S. Cl. 381/361; 438/51; 257/E21.002

(57) ABSTRACT

A MEMS microphone package is disclosed. The MEMS microphone package comprises a housing, a MEMS die and an ASIC chip. The housing includes a base, a sidewall extending from the base, and a cover supported by the sidewall for forming a receiving space. The housing defines an acoustic hole for receiving external sound waves. The MEMS die is accommodated in the housing and the MEMS die defines a plurality of first conductive pads. The ASIC chip is accommodated in the housing and the ASIC chip defines a plurality of second conductive pads.

### BACKGROUND OF THE INVENTION

1. Field of the Invention

The present invention generally relates to the art of microphones and, more particularly, to a micro-electro-mechanical-systems (MEMS) microphone package.

2. Description of Related Art

Silicon based condenser microphones, known as acoustic transducers, have been researched and developed for more than 20 years. Because of potential advantages in miniaturization, performance, reliability, environmental endurance, low cost, and mass production capability, silicon based microphones are widely recognized to be the next generation product to replace electret condenser microphones (ECM) that has been widely used in communication devices, multimedia players, and hearing aids.

For extreme miniaturization of a microphone, an electrical capacity structure is realized on a silicon wafer in a die shape using semiconductor-manufacturing technology and micromachining technology. A silicon condenser microphone chip or a MEMS microphone chip is such a capacitive structure. MEMS microphone chips must be packaged for being protected against exterior interferences.

As disclosed in U.S. Pat. No. 7,166,910 B2, U.S. Pat. No. 7,242,089 B2, and U.S. Pat. No. 7,023,066 B2, such a capacitive microphone generally includes a MEMS die having a silicon substrate, a backplate arranged on the substrate, and a moveable diaphragm separated from the backplate for forming a capacitor. While external sound waves reach the diaphragm, the diaphragm will be activated to vibrate relative to the backplate, which changes the distance between the diaphragm and the backplate and changes the capacitance value. As a result, the sound waves are converted into electrical signals. In fact, the electrical signals converted from sound waves include noise signals and the currents of the electrical signals are tiny. Therefore, there's a need to provide an ASIC (Application Specific Integrated Circuit) chip to cancel the noise signals and to amplify the tiny currents. Generally, the ASIC chip is connected to the MEMS die by lead wires.

However, it is more difficult to miniaturize the volume of the microphone, because the lead wires occupies space thereof. So an improved MEMS microphone package is desired to overcome the disadvantage mentioned above.

### SUMMARY OF THE INVENTION

According to the present invention, a MEMS (Micro-Electro-Mechanical-System) microphone package comprises a housing, a MEMS die and an ASIC chip. The housing includes a base, a sidewall extending from the base, and a cover supported by the sidewall for forming a receiving space. The housing defines an acoustic hole for receiving external sound waves. The MEMS die is accommodated in the housing and the MEMS die defines a plurality of first conductive pads. The ASIC chip is accommodated in the housing and the ASIC chip defines a plurality of second conductive pads. The housing defines a plurality of first conductive areas for electrically connecting to the first conductive pads, a plurality of second conductive areas for connecting to the second conductive pads, and a circuit embedded therein for electrically connecting the first conductive areas to the second conductive areas.

Other features of the present invention will become more apparent to those skilled in the art upon examination of the following drawings and detailed description of exemplary embodiments.

### BRIEF DESCRIPTION OF THE DRAWINGS

FIG. 1 is a schematic cross-sectional view of a MEMS microphone package in accordance with a first embodiment of the present invention;

FIG. 2 is a schematic cross-sectional view of a MEMS microphone in accordance with a second embodiment of the present invention;

FIG. 3 a schematic cross-sectional view of a MEMS microphone in accordance with a third embodiment of the present invention; and

FIG. 4 is a schematic cross-sectional view of a MEMS microphone in accordance with a fourth embodiment of the present invention.

### DETAILED DESCRIPTION OF THE PREFERRED EMBODIMENT

Reference will now be made to describe the exemplary embodiments of the present invention in detail.

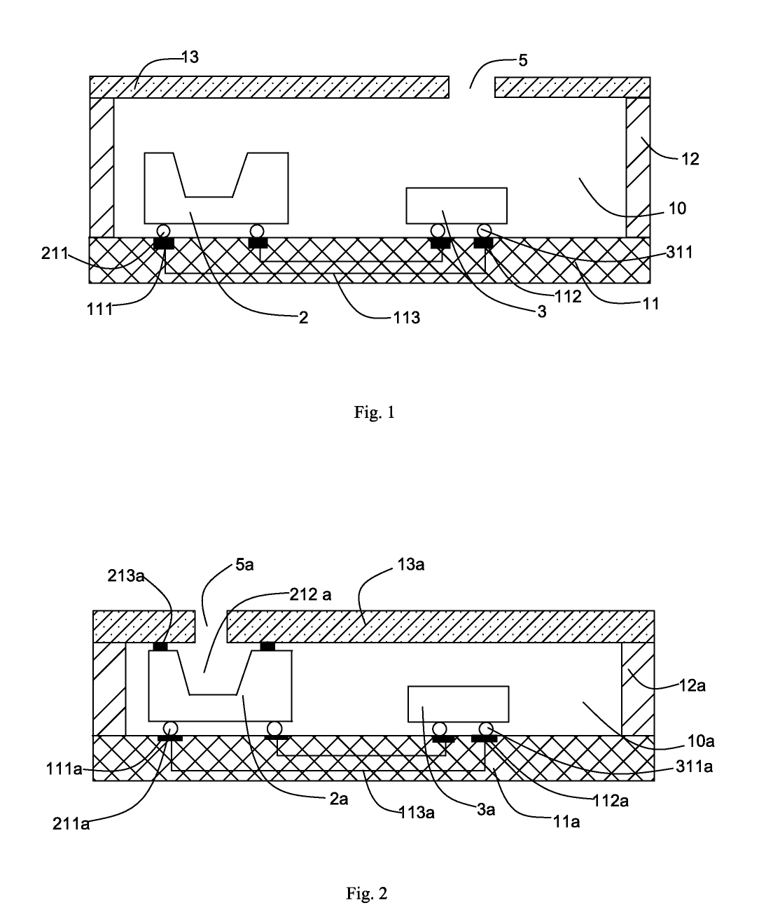

Referring to FIG. 1, a MEMS microphone package of a first embodiment of the present invention is disclosed. The MEMS microphone package includes a base 11, a sidewall 12 extending from the base 11, and a cover 13 supported by the sidewall 12. The combination of the base 11, the sidewall 12 and the cover 13 forms a housing for providing a receiving space 10. The housing defines an acoustic hole 5 for receiving external sound waves into the receiving space 10. The MEMS microphone package further includes a MEMS die 2 and a chip 3, such as an ASIC (Application Specific Integrated Circuit) chip 3 accommodated in the receiving space 10. As shown in FIG. 1, the MEMS die 2 and the ASIC chip 3 are both mounted on the base 11. The MEMS die 2 defines a plurality of first conductive pads 211, and the ASIC chip 3 defines a plurality of second conductive pads 311. Corresponding to the first conductive pads 211 and the second conductive pads 311 respectively, the base 11 defines a plurality of first conductive areas 111 and a plurality of second conductive areas 112. The MEMS die 2 is electrically connected to the base 11 by the electrical connection between the first conductive pads 211 and the first conductive areas 111. The ASIC chip 3 is electrically connected to the base 11 by the electrical connection between the second conductive pads 311 and the second conductive areas 112. The base 11 has circuits 113 embedded therein for electrically connecting the first conductive areas 111 to the second conductive areas 311. Thus, the MEMS die 2 is electrically connected to the ASIC chip 3 without lead wires.

Referring to FIG. 2, a MEMS microphone package of a second embodiment of the present invention is disclosed. The MEMS microphone package includes a base 11a, a sidewall 12a extending from the base 11a, and a cover 13a supported by the sidewall 12a. The combination of the base 11a, the sidewall 12a and the cover 13a forms a housing for providing a receiving space 10a. The cover 13a defines an acoustic hole 5a for receiving external sound waves. The MEMS microphone package further includes a MEMS die 2a and an ASIC chip 3a accommodated in the receiving space 10a. As shown in FIG. 2, the MEMS die 2a and the ASIC chip 3a are both mounted on the base 11a. The MEMS die 2a defines a plurality of first conductive pads 211a, and the ASIC chip 3a defines a plurality of second conductive pads 311a. Corresponding to the first conductive pads 211a and the second conductive pads 311a respectively, the base 11a defines a plurality of first conductive areas 111a and a plurality of second conductive areas 112a. The MEMS die 2a is electrically connected to the base 11a by the electrical connection between the first conductive pads 211a and the first conductive areas 111a. The ASIC chip 3a is electrically connected to the base 11a by the electrical connection between the second conductive pads 311a and the second conductive areas 112a. The base 11a has circuits 113a embedded therein for electrically connecting the first conductive areas 111a to the second conductive areas 311a. Thus, the MEMS die 2a is electrically connected to the ASIC chip 3a without lead wires. In addition, the MEMS die 2a defines a back volume 212a overlapping a part of the acoustic hole 5a. Moreover, a sealing belt 213a is provided between the cover 13a and the MEMS die 2a for isolating the back volume 212a from the receiving space 10a, which enables the sound waves directly reaches the back volume 212a without leak.

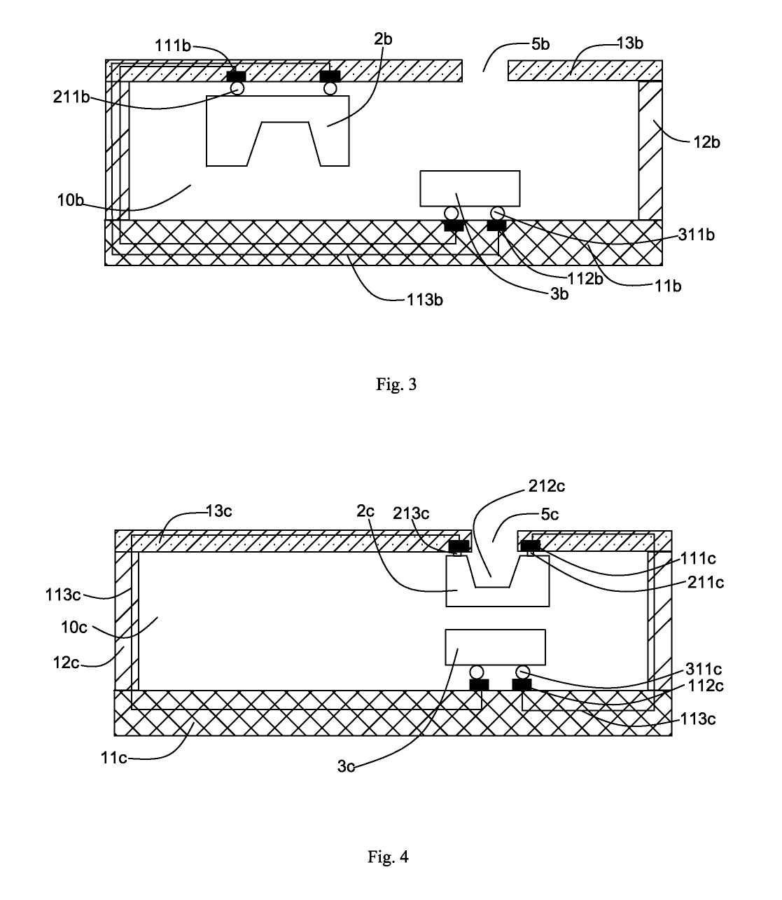

Referring to FIG. 3, a MEMS microphone package of a third embodiment of the present invention is disclosed. The MEMS microphone package includes a base 11b, a sidewall 12b extending from the base 11b, and a cover 13b supported by the sidewall 12b. The combination of the base 11b, the sidewall 12b and the cover 13b forms a housing for providing a receiving space 10b. The cover 13b defines an acoustic hole 5b for receiving external sound waves into the receiving space 10b. The MEMS microphone package further includes a MEMS die 2b and an ASIC chip 3b accommodated in the receiving space 10b. As shown in FIG. 3, the MEMS die 2b is mounted on the cover and the ASIC chip 3b is mounted on the base 11b. The MEMS die 2b defines a plurality of first conductive pads 211b, and the ASIC chip 3b defines a plurality of second conductive pads 311b. Corresponding to the first conductive pads 211b, the cover 13b defines a plurality of first conductive areas 111b. Corresponding to the second conductive pads 311b, the base 11b defines a plurality of second conductive areas 112b. Thus, the MEMS die 2b is electrically connected to the cover 13b by the electrical connection between the first conductive pads 211b and the first conductive areas 111b. The ASIC chip 3b is electrically connected to the base 11b by the electrical connection between the second conductive pads 311b and the conductive areas 112b. The housing has circuits 113b embedded therein for electrically connecting the first conductive areas 111b to the second conductive areas 311b, which enables the MEMS die 2b to be electrically connected to the ASIC chip 3b without lead wires.

Referring to FIG. 4, a MEMS microphone package in accordance with a fourth embodiment is disclosed. The MEMS microphone package includes a base 11c, a sidewall 12c extending from the base 11c, and a cover 13c supported by the sidewall 12c. The combination of the base 11c, the sidewall 12c and the cover 13c forms a housing for providing a receiving space 10c. The cover 13c defines an acoustic hole 5c for receiving external sound waves. The MEMS microphone package further includes a MEMS die 2c and an ASIC chip 3c accommodated in the housing. MEMS die 2c is mounted on the cover 13c with the back volume 212c overlapping the acoustic hole 5c. A sealing belt 213c is provided for isolating the back volume 212c from the receiving space 10c. The sealing belt 213c defines a plurality of first conductive pads 211c for electrically connecting to the first conductive areas 111c on the cover 13c. The ASIC chip 3c is mounted on the base 11c by second conductive pads 311c and the second conductive areas 112c. The MEMS die 2c is electrically connected to the ASIC chip 3c by circuits 113c embedded in the housing.

MEMS microphone packages of the present invention have volumes smaller than the conventional packages.

A method of manufacturing a MEMS microphone package in accordance with a first embodiment is disclosed. Referring to FIG. 1, the method is that providing a MEMS die 2 defining a plurality of first conductive pads 211, an ASIC chip 3 defining a plurality of second conductive pads 311, and a housing defining a plurality of first conductive areas 111 for electrically connecting to the first conductive pads 211 and a plurality of second conductive areas 112 for connecting to the second conductive pads 311, embodying a circuit 113 in the housing, accommodating the MEMS die 2 and the ASIC die 3 in the housing, electrically connecting the first conductive pads 211 to the second conductive pads 112 by the circuit 113. The housing also defines an acoustic hole 5 for receiving external sound waves. The housing comprises a base 11, a sidewall 12 extending from the base 11, and a cover 13 supported by the sidewall 12 for forming a receiving space 10. As shown in FIG. 1, both the MEMS die 2 and the ASIC chip 3 are mounted on the base 11, and the circuit 113 is defined in the base 11.

A method of manufacturing a MEMS microphone package in accordance with a second embodiment is disclosed. Referring to FIG. 2, the method is that providing a MEMS die 2a defining a plurality of first conductive pads 211a, an ASIC chip 3a defining a plurality of second conductive pads 311a, and a housing defining a plurality of first conductive areas 111a for electrically connecting to the first conductive pads 211a and a plurality of second conductive areas 112a for connecting to the second conductive pads 311a, embodying a circuit 113a in the housing, accommodating the MEMS die 2a and the ASIC die 3a in the housing, electrically connecting the first conductive pads 211a to the second conductive pads 112a by the circuit 113a. The housing also defines an acoustic hole 5a for receiving external sound waves. The housing comprises a base 11a, a sidewall 12a extending from the base 11a, and a cover 13a supported by the sidewall 12a for forming a receiving space 10a. As shown in FIG. 1, both the MEMS die 2a and the ASIC chip 3a are mounted on the base 11a, and the circuit 113a is defined in the base 11a. The acoustic hole 5a is defined in the cover 13a and a back volume 212a is defined in the MEMS die 2a, the back volume 212a is overlapping a part of the acoustic hole 5a. A sealing belt 213a is arranged between the cover 13a and the MEMS die 2a, the back volume 212a is isolated to the receiving space 10a by the sealing belt 213a.

A method of manufacturing a MEMS microphone package in accordance with a third embodiment is disclosed. Referring to FIG. 3, the method is that providing a MEMS die 2b defining a plurality of first conductive pads 211b, an ASIC chip 3b defining a plurality of second conductive pads 311b, and a housing defining a plurality of first conductive areas 111b for electrically connecting to the first conductive pads 211b and a plurality of second conductive areas 112b for connecting to the second conductive pads 311b, embodying a circuit 113b in the housing, accommodating the MEMS die 2b and the ASIC die 3b in the housing, electrically connecting the first conductive pads 211b to the second conductive pads 112b by the circuit 113b. The housing also defines an acoustic hole 5b for receiving external sound waves. The housing comprises a base 11b, a sidewall 12b extending from the base 11b, and a cover 13b supported by the sidewall 12b for forming a receiving space 10b. As shown in FIG. 1, both the MEMS die 2b and the ASIC chip 3b are mounted on the base 11b, and the circuit 113b is defined in the base 11b. The MEMS die 2b is mounted on the cover 13b by electrical connection between the first conductive pads 111b and the first conductive areas 211b, and the ASIC chip 3b is mounted on the base 11b by electrical connection between the second conductive pads 311b and the conductive areas 112b.

A method of manufacturing a MEMS microphone package in accordance with a fourth embodiment is disclosed. Referring to FIG. 4, the method is that providing a MEMS die 2c defining a plurality of first conductive pads 211c, an ASIC chip 3 defining a plurality of second conductive pads 311c, and a housing defining a plurality of first conductive areas 111 for electrically connecting to the first conductive pads 211c and a plurality of second conductive areas 112c for connecting to the second conductive pads 311c, embodying a circuit 113c in the housing, accommodating the MEMS die 2c and the ASIC die 3c in the housing, electrically connecting the first conductive pads 211 to the second conductive pads 112c by the circuit 113c. The housing also defines an acoustic hole 5c for receiving external sound waves. The housing comprises a base 11c, a sidewall 12c extending from the base 11c, and a cover 13c supported by the sidewall 12c for forming a receiving space 10c. As shown in FIG. 1, both the MEMS die 2c and the ASIC chip 3c are mounted on the base 11c, and the circuit 113c is defined in the base 11c. A back volume 212c is defined in the MEMS die 2c and the back volume 212c being overlapping the acoustic hole 5c. A sealing belt 213c is located between the cover 13c and the MEMS die 2c and the first conductive pads 211c is defined in the sealing belt 213c.

While the present invention has been described with reference to the specific embodiments, the description of the invention is illustrative and is not to be construed as limiting the invention. Various of modifications to the present invention can be made to the embodiments by those skilled in the art without departing from the true spirit and scope of the invention as defined by the appended claims.

What is claimed is:

1. A MEMS microphone package comprising:
a housing including a base, a sidewall extending from the base, and a cover supported by the sidewall for forming a receiving space, the housing defining an acoustic hole for receiving external sound waves;
a MEMS die accommodated in the housing, the MEMS die defining a plurality of first conductive pads;
a chip accommodated in the housing, the chip defining a plurality of second conductive pads; wherein
the housing defines a plurality of first conductive areas for electrically connecting to the first conductive pads, a plurality of second conductive areas for connecting to the second conductive pads, and a circuit embedded therein for electrically connecting the first conductive areas to the second conductive areas.

2. The MEMS microphone package as described in claim 1, wherein the MEMS die and the chip are both mounted on the base, and the circuit is defined in the base.

3. The MEMS microphone package as described in claim 2, wherein the acoustic hole is defined in the cover and the MEMS die includes a back volume overlapping a part of the acoustic hole.

4. The MEMS microphone package as described in claim 3 further comprising a sealing belt between the cover and the MEMS die for isolating the back volume from the receiving space.

5. The MEMS microphone package as described in claim 1, wherein the MEMS die is mounted on the cover by electrical connection between the first conductive pads and the first conductive areas, and the chip is mounted on the base by electrical connection between the second conductive pads and the conductive areas.

6. The MEMS microphone package as described in claim 1, wherein the chip is mounted on the base by electrical connection between the second conductive pads and the second conductive areas, and the MEMS die is mounted on the cover by electrical connection between the second conductive areas and the first conductive pads defined in a sealing belt located between the cover and the MEMS die, the MEMS die being provided with a back volume overlapping the acoustic hole.

7. A method for manufacturing a MEMS microphone package, comprising the steps of:
providing a MEMS die, a chip and a housing for accommodating the MEMS die and chip;
providing the MEMS die with a plurality of first conductive pads;
providing the chip with a plurality of second conductive pads;
providing the housing with an acoustic hole for receiving external sound waves, a plurality of first conductive areas for electrically connecting to the first conductive pads, a plurality of second conductive areas for connecting to the second conductive pads, a base, a side wall extending from the base, a cover supported by the side wall for forming a receiving space and an circuit;
electrically connecting the first conductive pads to the second conductive pads by the circuit.

8. The method as described in claim 7, wherein the MEMS die and the ASIC chip are both mounted on the base, and the circuit is defined in the base.

9. The method as described in claim 8, wherein the acoustic hole is defined in the cover and a back volume is defined in the MEMS die, the back volume is overlapping a part of the acoustic hole.

10. The method as described in claim 9, comprising a step of providing a sealing belt arranged between the cover and the MEMS die for isolating the back volume to the receiving space.

11. The method as described in claim 7, wherein the MEMS die is mounted on the cover by electrical connection between the first conductive pads and the first conductive areas, and the chip is mounted on the base by electrical connection between the second conductive pads and the conductive areas.

12. The method as described in claim 7, wherein the chip is mounted on the base by electrical connection between the second conductive pads and the second conductive areas, while the MEMS die is mounted on the cover by electrical connection between the second conductive areas; and the MEMS die defines a back volume overlapping the acoustic hole, and a sealing belt is located between the cover and the MEMS die for providing the first conductive pads.
